(19) United States
(12) Patent Application Publication
(10) Pub. No.: US 2026/0165086 A1
(43) Pub. Date: Jun. 11, 2026

(54) TRANSFER ROBOT AND SUBSTRATE PROCESSING APPARATUS

(71) Applicant: SEMES CO., LTD., Cheonan-si (KR)

(72) Inventors: Na Hyun LEE, Ansan-si (KR); Myung Jin LEE, Hwaseong-si (KR); Kyo Bong KIM, Seongnam-si (KR); Min Seong KIM, Hwaseong-si (KR)

(73) Assignee: SEMES CO., LTD., Cheonan-si (KR)

(21) Appl. No.: 19/416,736

(22) Filed: Dec. 11, 2025

(30) Foreign Application Priority Data
Dec. 11, 2024 (KR) 10-2024-0183819

(51) Int. Cl. H10P 72/76; B25J 11/00; B25J 15/00

(52) U.S. Cl. CPC H10P 72/7602; B25J 11/0095; B25J 15/0014; B25J 15/0052

(57) ABSTRACT

Provided is a transfer robot for transferring a substrate, the transfer robot including: a hand assembly including a hand supporting a substrate and a hand support connected to the hand; and a driving unit for driving the hand assembly, in which wherein the hand includes: a support plate coupled to the hand support to support the substrate; a fixed guide which is fixedly installed on a front end of an upper surface of the support plate to support a region of a lower surface of an edge of the substrate placed on the support plate; a rotary guide located at a rear end of the upper surface of the support plate so as to be spaced apart from the fixed guide to support the region of the lower surface of the edge of the substrate; and a guide driving unit for driving the rotary guide.

### CROSS-REFERENCE TO RELATED APPLICATION

This application claims priority to and the benefit of Korean Patent Application No. 10-2024-0183819 filed in the Korean Intellectual Property Office on Dec. 11, 2024, the entire contents of which are incorporated herein by reference.

### TECHNICAL FIELD

The present invention relates to a transfer robot and a substrate processing apparatus, and more particularly, to a transfer robot that transfers a substrate and a substrate processing apparatus including the same.

### BACKGROUND ART

To manufacture a semiconductor device or liquid crystal display, various processes, such as photolithography, etching, ashing, ion implantation, and thin film deposition, are performed on a substrate. Before or after such a process proceeds, a cleaning process is performed to clean the substrate to remove contaminants and particles generated in each process. In general, the cleaning process includes a process of liquid-treating a substrate. Since the substrate before processing before the cleaning process contains contaminants, such as particles and fumes, there is a problem of reverse contamination of a hand and the substrate when the contaminated (dirty) substrate before processing and the clean substrate after the cleaning process are transferred using the same hand. Accordingly, a method of transferring the substrate before processing and the substrate after the cleaning process using different hands is known.

However, when the substrate before processing and the substrate after processing are transferred using different hands, not only does the number of hands increase, but also the size of the transfer robot increases, and the hand that can transfer the substrate varies depending on whether the substrate has been processed or not, so there is a problem that the transfer efficiency of the substrate is reduced.

### SUMMARY OF THE INVENTION

The present invention has been made in an effort to provide a transfer robot capable of improving substrate transfer efficiency and a substrate processing apparatus including the same.

The present invention has also been made in an effort to provide a transfer robot with simplified configurations and a substrate processing apparatus including the same.

The present invention has also been made in an effort to provide a transfer robot capable of transferring a substrate before processing and a substrate after processing through one hand and preventing the substrate from being contaminated, and a substrate processing apparatus including the same.

The objectives of the present disclosure are not limited thereto and other objectives not stated herein may be clearly understood by those skilled in the art from the following description.

An exemplary embodiment of the present disclosure, a transfer robot for transferring a substrate, the transfer robot comprising: a hand assembly including a hand supporting a substrate and a hand support connected to the hand; and a driving unit for driving the hand assembly, wherein the hand includes: a support plate coupled to the hand support to support the substrate; a fixed guide which is fixedly installed on a front end of an upper surface of the support plate to support a region of a lower surface of an edge of the substrate placed on the support plate; a rotary guide located at a rear end of the upper surface of the support plate so as to be spaced apart from the fixed guide to support the region of the lower surface of the edge of the substrate; and a guide driving unit for driving the rotary guide, the fixed guide includes: a first fixed support part for supporting the substrate at a first height; and a second fixed support part for supporting the substrate at a second height different from the first height, the rotary guide is rotatably provided with respect to the support plate based on a rotation shaft and includes a body having a first rotary support surface capable of supporting the substrate at the first height together with the first fixed support part and a second rotary support surface capable of supporting the substrate at the second height together with the second fixed support part, and the guide driving unit is provided to rotate the body to switch between a first state in which the first rotary support surface supports the substrate together with the first fixed support part and a second state in which the second rotary support surface supports the substrate together with the second fixed support part.

According to the exemplary embodiment of the present invention, wherein the first rotary support surface and the second rotary support surface may be provided obliquely to each other.

According to the exemplary embodiment of the present invention, wherein the rotary guide further may includes, a first rotary guide surface for guiding a lateral surface of the substrate when the first rotary support surface supports the substrate; and a second rotary guide surface for guiding the lateral surface of the substrate when the second rotary support surface supports the substrate.

According to the exemplary embodiment of the present invention, wherein support protrusions for supporting a bottom surface of the substrate may be formed on the first rotary support surface and the second rotary support surface, respectively.

According to the exemplary embodiment of the present invention, wherein the guide driving unit may includes: a moving block provided to move horizontally on the hand support; and a link connecting the moving block and the rotary guide.

According to the exemplary embodiment of the present invention, wherein the rotary guide further includes: a first hinge connected to the hand assembly; and a second hinge to which one end of the link is connected, the moving block includes a third hinge to which the other end of the link is connected, and the first hinge maay be a rotation shaft on which the rotary guide rotates.

According to the exemplary embodiment of the present invention, wherein when the rotary guide is in the first state, the rotation shaft is disposed below the first rotary support surface, and when the rotary guide is in the second state, the rotation shaft maay be disposed below the second rotary support surface.

According to the exemplary embodiment of the present invention, wherein the fixed guide may includes, a first fixed support surface provided as the first fixed support part; and a second fixed support surface provided as the second fixed support part.

According to the exemplary embodiment of the present invention, wherein the support plate includes: a connection part coupled to the hand support; and a first finger and a second finger extending from the connection part, and the fixed guide may be provided to each of front ends of the first finger and the second finger.

According to the exemplary embodiment of the present invention, wherein a plurality of hand assemblies are provided, and the plurality of hand assemblies may be provided to be spaced apart from each other in a vertical direction.

According to the exemplary embodiment of the present invention, wherein the hand assembly may be provided so that one or more hands are coupled to one hand support to be spaced apart in the vertical direction.

According to the exemplary embodiment of the present invention, wherein the transfer robot further includes: a base; and an arm of which one end is connected to the base and the other end is connected to the hand assembly, and the arm may be provided to be movable forward and backward with respect to the base.

According to the exemplary embodiment of the present invention, wherein when viewed from the top, a center position of the substrate when the fixed guide and the rotary guide support the substrate at the first height and a center position of the substrate when the fixed guide and the rotary guide support the substrate at the second height may be provided differently.

An exemplary embodiment of the present disclosure, an apparatus for processing a substrate, the apparatus comprising: an index module including a load port for loading and unloading a substrate; a treating module including a process chamber for processing a substrate; and a controller; and the transfer robot of claim 1 for transferring the substrate between the index module and the treating module, wherein the controller switches a state of the rotary guide to transfer the substrate in a state where the hand supports a first substrate and a second substrate at different heights when the hand transfers the first substrate and the second substrate.

According to the exemplary embodiment of the present invention, wherein the fixed guide may includes, a first fixed support surface provided as the first fixed support part; and a second fixed support surface provided as the second fixed support part.

According to the exemplary embodiment of the present invention, wherein the first substrate is a substrate before processing that has not been processed in the process chamber, and the second substrate is a substrate after processing that has been processed in the process chamber, and the controller controls the fixed guide and the rotary guide to support the substrate before processing at the first height by switching the rotary guide to the first state when the hand transfers the substrate before processing, and the controller may controls the fixed guide and the rotary guide to support the substrate after processing at the second height by switching the rotary guide to the second state when the hand transfers the substrate after processing.

According to the exemplary embodiment of the present invention, wherein when viewed from the top, a center position of the substrate when the fixed guide and the rotary guide support the substrate at the first height and a center position of the substrate when the fixed guide and the rotary guide support the substrate at the second height may be provided differently.

An exemplary embodiment of the present disclosure, a transfer robot for transferring a substrate, the transfer robot comprising: a base; an arm which is connected to the base and is movable forward and backward with respect to the base; a hand assembly including a hand coupled to the arm and supporting the substrate and a hand support connected to the hand; and a driving unit for driving the hand assembly, wherein the hand includes: a support plate coupled to the hand support to support the substrate; a fixed guide which is fixedly installed on a front end of an upper surface of the support plate to support a region of a lower surface of an edge of the substrate placed on the support plate; a rotary guide located at a rear end of the upper surface of the support plate so as to be spaced apart from the fixed guide to support the region of the lower surface of the edge of the substrate; and a guide driving unit for driving the rotary guide, the support plate includes: a connection part coupled to the arm; and a first finger and a second finger extending from the connection part, and the fixed guide is provided to each of front ends of the first finger and the second finger, the fixed guide includes: a first fixed support surface for supporting the substrate at a first height; and a second fixed support surface for supporting the substrate at a second height different from the first height, the rotary guide is rotatably provided with respect to the support plate based on a rotation shaft and includes a body having a first rotary support surface capable of supporting the substrate at the first height together with the first fixed support surface and a second rotary surface capable of supporting the substrate at the second height together with the second fixed support surface, the guide driving unit is provided to rotate the rotary guide so that the rotary guide switches between a first state supporting the substrate at the first height and a second state supporting the substrate at the second height, the first state is a state in which the first fixed support surface and the first rotary support surface support the substrate at the first height, and the second state may be a state in which the second fixed support surface and the second rotary support surface support the substrate at the second height.

According to the exemplary embodiment of the present invention, wherein a plurality of hand assemblies are provided, and the plurality of hand assemblies are provided to be spaced apart from each other in a vertical direction, and each of the hand assemblies may be provided so that one or more hands are coupled to one hand support to be spaced apart in the vertical direction.

According to the exemplary embodiment of the present invention, the transfer robot may further include a controller, the controller controls the fixed guide and the rotary guide to support the substrate before processing at the first height by switching the rotary guide to the first state when the hand supports the substrate before processing, and the controller may controls the fixed guide and the rotary guide to support the substrate after processing at the second height by switching the rotary guide to the second state when the hand supports the substrate after processing.

According to the exemplary embodiment of the present invention, it is possible to improve substrate transfer efficiency.

Further, according to the exemplary embodiment of the present invention, it is possible to simplify the configuration of the transfer robot.

Further, according to the exemplary embodiment of the present invention, it is possible to transfer a substrate before processing and a substrate after processing through one hand and prevent the substrate from being contaminated.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a diagram schematically illustrating a substrate processing apparatus according to an exemplary embodiment of the present invention.

FIG. 2 is a perspective view illustrating a first transfer robot according to a first exemplary embodiment of the present invention.

FIG. 3 is a perspective view illustrating a hand assembly of FIG. 2 according to an exemplary embodiment of the present invention.

FIG. 4 is a diagram schematically illustrating a guide driving unit of FIG. 3.

FIG. 5 is a diagram illustrating a state where a rotary guide of FIG. 4 is in a first state, and

FIG. 6 is a diagram illustrating a state where the rotary guide of FIG. 4 is in a second state.

FIG. 7 is a diagram schematically illustrating a state when a hand of FIG. 3 supports the substrate at a first height, and FIG. 8 is a diagram schematically illustrating a state when the hand of FIG. 3 supports the substrate at a second height.

FIG. 9 is a diagram schematically illustrating driving of a hand of a first transfer robot of FIG. 2.

FIG. 10 is a flowchart illustrating a method of processing a substrate using the above-described substrate processing apparatus.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, the present invention will be described based on a process of liquid-treating a substrate W by supplying a liquid, such as a cleaning liquid, onto a substrate W as an example. However, the present exemplary embodiment is not limited to the cleaning process, and may be applied to various processes of processing the substrate W using a liquid, such as an etching process, an ashing process, or a developing process.

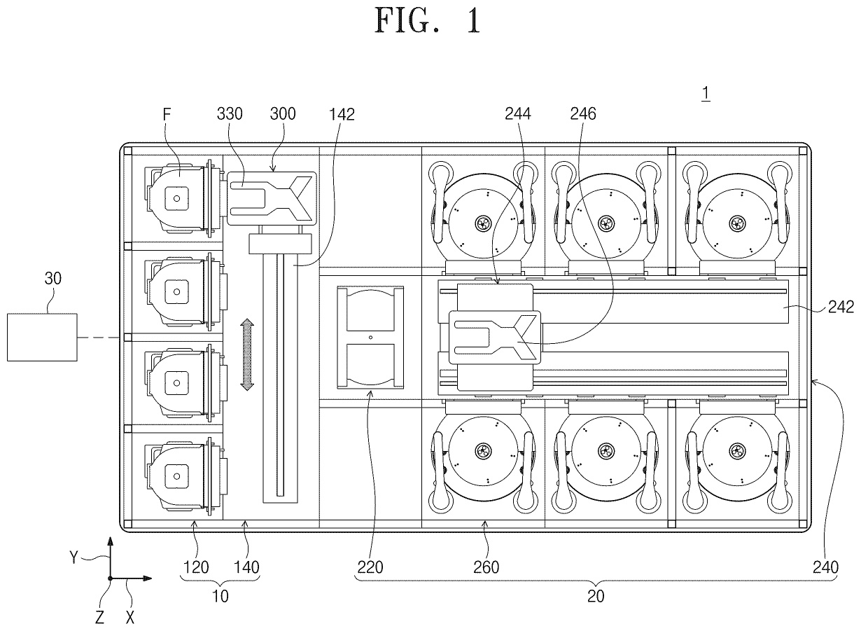

Hereinafter, an exemplary embodiment of the present invention will be described in detail with reference to FIGS. 1 to 10. A substrate processing apparatus 1 according to an exemplary embodiment of the present invention may perform a cleaning process including a drying process of drying a substrate W using a process fluid.

FIG. 1 is a top plan view schematically illustrating a substrate processing apparatus according to an exemplary embodiment of the present invention. Referring to FIG. 1, a substrate processing apparatus 1 includes an index module 10, a treating module 20, and a controller 30. According to an example, the index module 10 and the treating module 20 are disposed along one direction. Hereinafter, a direction in which the index module 10 and the treating module 20 are arranged is defined as a first direction X. When viewed from the top, a direction perpendicular to the first direction X is defined as a second direction Y, and a direction perpendicular to a plane including both the first direction X and the second direction Y is defined as a third direction Z.

The index module 10 transfers a substrate W from a container F in which the substrate W is accommodated to the treating module 20 processing the substrate W. The index module 10 accommodates the substrate W completely processed in the treating module 20 in the container F. A longitudinal direction of the index module 10 is provided in the second direction Y. The index module 10 includes a load port 120 and an index frame 140.

The container F in which the substrate W is accommodated is seated on the load port 120. Based on the index frame 140, the load port 120 is located at a side opposite to the treating module 20. A plurality of load ports 120 may be provided. The plurality of load ports 120 may be arranged in a line along the second direction Y. The number of load ports 120 may increase or decrease according to the process efficiency and footprint conditions of the treating module 20.

A plurality of slots (not illustrated) is formed in the container F. The slots (not illustrated) may accommodate the substrates W in a state in which the substrates W are disposed horizontally with respect to the ground. As the container F, an airtight container, such as a Front Open Unified Pod (FOUP), may be used. The container F may be placed on the load port 120 by a transfer means (not illustrated), such as an overhead transfer, an overhead conveyor, or an automatic guided vehicle, or an operator.

An index rail 142 and a first transfer robot 300 are provided inside the index frame 140. The index rail 142 is provided in the index frame 140 along the second direction Y in its longitudinal direction. The first transfer robot 300 may transfer the substrate W.

The first transfer robot 300 may transfer the substrate W between the index module 10 and the treating module 20. The first transfer robot 300 may transfer the substrate W between the load port 120 and a buffer chamber 220 to be described below. The first transfer robot 300 may be called as an index robot. A detailed configuration of the first transfer robot 300 will be described later.

The first transfer robot 300 includes a plurality of hands 330. The substrate W is seated on the hand 330. The first transfer robot 300 may be provided to be movable on the index rail 142 along the second direction Y. Accordingly, the hand 330 may be moved forward and backward along the index rail 142. Also, the first transfer robot 300 may be provided to be rotatable with respect to the third direction Z as an axis. Also, the first transfer robot 300 may be provided to be movable vertically along the third direction Z. The first transfer robot 300 will be described later.

The controller 30 controls the substrate processing apparatus 1. The controller 30 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a treatment recipe, for executing the process in each component according to various data and treatment conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus 1 to perform a substrate processing method described below. For example, the controller 30 may control the configurations provided to the first transfer robot 300, a second transfer robot 244, and a process chamber 260 so as to perform a substrate processing method described below.

The treating module 20 includes a buffer chamber 220, a transfer frame 240, and a process chamber 260. The buffer chamber 220 provides a space in which the substrate W loaded into the treating module 20 and the substrate W unloaded from the treating module 20 stay temporarily. The transfer frame 240 provides a transfer space for transferring the substrate W between the buffer chamber 220 and the process chamber 260.

The buffer chamber 220 may be disposed between the index frame 140 and the transfer chamber 240. The buffer chamber 220 may be located at one end of the transfer frame 240. A slot (not illustrated) in which the substrate W is placed is provided in the buffer chamber 220. A plurality of slots (not illustrated) is provided. A plurality of slots (not illustrated) may be disposed to be spaced apart from each other along the third direction Z. A front face and a rear face of the buffer chamber 220 are opened. The front face is a face facing the index module 10, and the rear face is a face facing the transfer frame 240. The first transfer robot 1 may approach the buffer chamber 220 through the front face, and the second transfer robot 244 may approach the buffer chamber 220 through the rear face.

A longitudinal direction of the transfer frame 240 may be provided along the first direction X. The process chambers 260 may be disposed on opposite sides of the transfer frame 240. The process chamber 260 may be disposed on a side portion of the transfer frame 240. The transfer frame 240 and the process chamber 260 may be disposed along the second direction Y.

According to the example, the process chambers 260 are disposed on opposite sides of the transfer frame 240. At one side of the transfer frame 240, the process chambers 260 may be provided in an array of A×B (each of A and B is 1 or a natural number larger than 1) in the first direction X and the third direction Z. Herein, A is the number of process chambers 260 provided in a row along the first direction X, and B is the number of process chambers 260 provided in a row along the third direction Z. For example, when six process chambers 260 are provided at one side of the transfer frame 240, the process chambers 260 may be arranged in a 3×2 array. The number of process chambers 260 may increase or decrease. Unlike the above description, the process chambers 260 may be provided as a single layer on one side and opposite sides of the transfer frame 240.

The transfer frame 240 includes a guide rail 242 and a transfer robot 244. The guide rail 242 is provided within the transfer frame 240 in the first direction X in a longitudinal direction thereof. The second transfer robot 244 may be provided on the guide rail to be able to move linearly in the first direction X. The second transfer robot 244 transfers the substrate W between the buffer chamber 220 and the process chamber 260.

The process chamber 260 may process the substrate W. The process chamber 260 may be a chamber for performing a cleaning process for removing process by-products or the like attached to the substrate W. The process chamber 260 may be provided as, for example, a liquid treating chamber 400 to perform a liquid treatment process of liquid-treating the substrate W by supplying a liquid onto the substrate W. Hereinafter, the present invention will be described based on the case where the process chamber 260 is the liquid treating chamber 400 as an example. The liquid treating chamber 400 may process the substrate W by supplying a chemical, a rinse liquid, and/or an organic solvent onto the substrate W. The processing of the substrate W performed in the liquid treating chamber 400 may include a spin drying treatment in which the liquid remaining on the substrate W is removed by rotating the substrate W.

The process chamber 260 may have different structures depending on the type of process for processing the substrate W. Alternatively, each of the process chambers 260 may have the same structure.

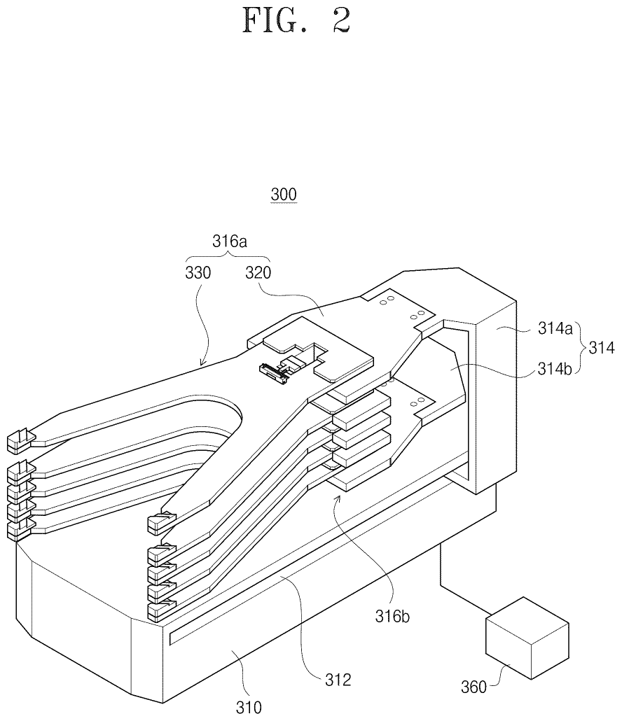

FIG. 2 is a perspective view illustrating the first transfer robot according to a first exemplary embodiment of the present invention. Referring to FIG. 2, the first transfer robot 300 includes a base 310, an arm 314, a hand assembly 316, and a driving unit 360.

The base 310 supports the arm 314 and the hand assembly 316 connected to the arm 314. The arm 314 is connected with the base 310. An end of the arm 314 is connected to the hand assembly 316.

The base 310 is installed to be movable along the index rail 142. The base 310 may be axially rotated with respect to a support axis (not shown) in the third direction Z. The base 310 may have a generally rectangular parallelepiped shape. The base 310 is provided such that a longitudinal direction thereof is directed in a horizontal direction. A guide 312 is provided on the base 310. The guide 312 guides the moving direction of the arm 314 so that the arm 314 and the hand assembly 316 coupled to the arm 314 may move linearly along the longitudinal direction of the base 310. A plurality of guides 312 may be provided. The arm 314 is provided to be able to move forward and backward with respect to the base 310 by the driving unit 360. According to an example, the same number of guides 312 as the arm 314 may be provided. Each of the guides 312 may be provided such that a longitudinal direction thereof is parallel to the base 310.

The arm 314 and the hand assembly 316 coupled to the arm 314 may be stacked on the base 310 to be spaced apart from each other in a vertical direction and may be provided in plural. A plurality of arms 314 may linearly move independently of each other by the driving unit 360.

In the present embodiment, the first transfer robot 300 includes two arms 314 and two hand assemblies 316, but the number of arms 314 and the number of hand assemblies 316 may be freely changed according to the process efficiency of the substrate processing apparatus 1.

The hand assembly 316 includes a hand support 320 and a hand 330 connected to the arm 314. A guide driving unit 350 to be described later may be installed on the hand support 320. The hand 330 is coupled to the hand support 320.

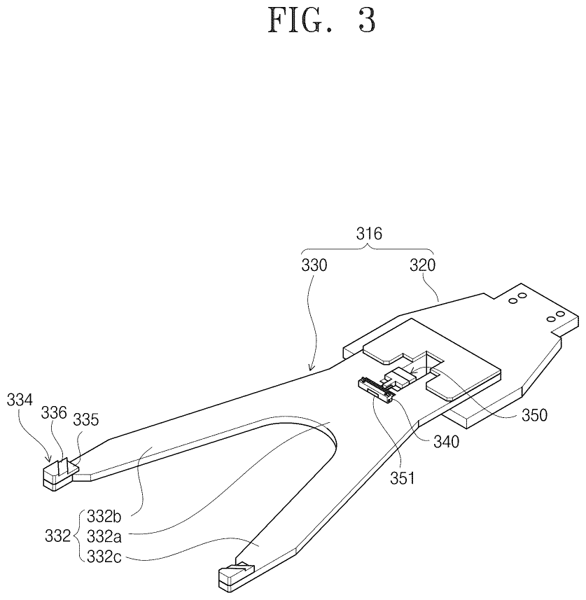

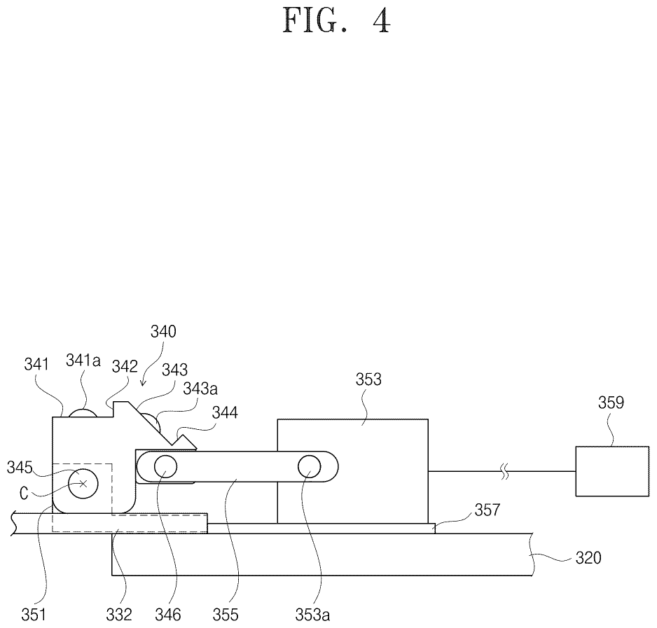

FIG. 3 is a perspective view illustrating the hand assembly of FIG. 2 according to the exemplary embodiment of the present invention, and FIG. 4 is a diagram schematically illustrating the guide driving unit of FIG. 3.

Hereinafter, the hand assembly 316 according to the exemplary embodiment of the present invention will be described in detail with reference to FIGS. 3 to 4.

The hand 330 includes a support plate 332, a fixed guide 334, a rotary guide 340, and the guide driving unit 350.

The support plate 332 is coupled to the hand support 320. The support plate 332 includes a connection part 332a, a first finger 332b, and a second finger 332c.

The first finger 332b and the second finger 332c have a rod shape, are positioned to face each other while being spaced apart from each other, and extend in the same direction from the connection part 332a. Opposite sides of a front end of the connection part 332 are connected to the first fingerer 332 and the second fingerer 334, respectively, and a base end of the connection part 336 is connected to the hand support 320. The base end of the connection part 332a may be coupled to the hand support 320. The fixed guide 334 may support a lower surface region of an edge of the substrate W placed on the hand 330, and simultaneously restrict a lateral movement of the substrate W by guiding a lateral surface of the substrate W.

The fixed guides 334 may be provided at front ends of the first finger 332b and the second finger 332c of the support plate 332, respectively. The fixed guides 334 may be installed on upper surfaces of the first finger 332b and the second finger 332c. The fixed guide 334 may be fixedly installed on the front end of the upper surface of the support plate 332. The substrate W may be seated on the fixed guide 334.

The fixed guide 334 includes a first fixed support part supporting the substrate W at a first height h1 and a second fixed support part supporting the substrate W at a second height h2. The first height h1 and the second height h2 may be different from each other.

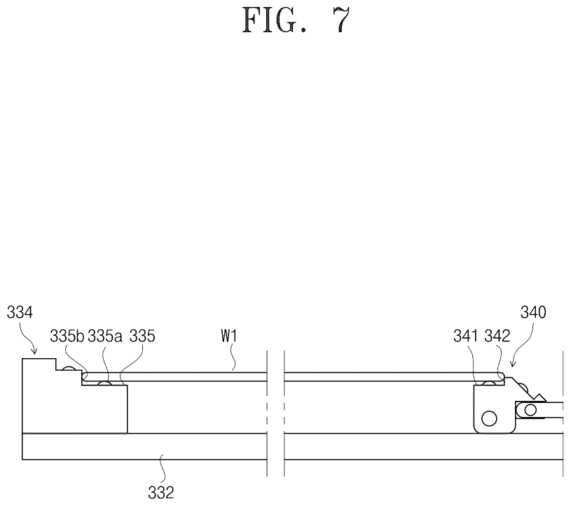

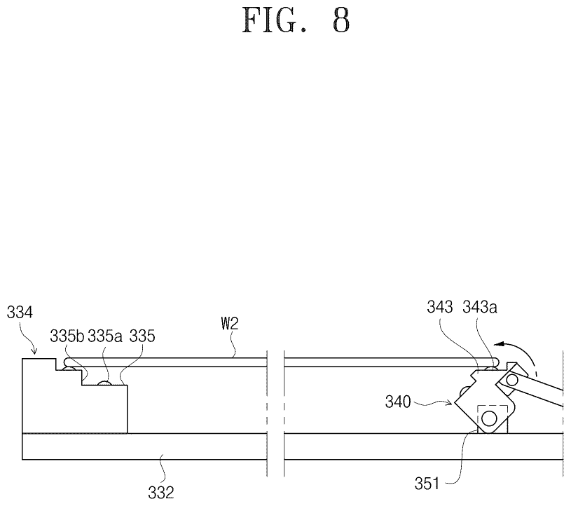

FIG. 7 is a diagram schematically illustrating a state when the hand of FIG. 3 supports the substrate at the first height, and FIG. 8 is a diagram schematically illustrating a state when the hand of FIG. 3 supports the substrate at the second height. A detailed configuration of the fixed guide 334 will be described with reference to FIGS. 3, 7, and 8.

The fixed guide 334 may include a first fixed support surface 335, a first fixed guide surface 335b, a second fixed support surface 336, and a second fixed guide surface 336b.

In the present embodiment, it is illustrated and described that the first fixed support surface 335 is a first fixed support part that supports the substrate W at the first height h1, and the second fixed support surface 336 is a second fixed support part that supports the substrate W at the second height h2. The fixed guide 334 may be stepped to provide the first fixed support surface 335 and the second fixed support surface 336 having different heights.

A support protrusion 355a for supporting a lower surface of the substrate W when the substrate W is placed on the first fixed support surface 335 may be formed on the first fixed support surface 335.

The first fixed guide surface 335b may be provided adjacent to the first fixed support surface 335. The first fixed guide surface 335b may be provided to be perpendicular to the first fixed support surface 335. The first fixed guide surface 335b may face the end of the substrate W in a state in which the lower surface of the substrate W is supported by the first fixed support surface 335. When the first fixed support surface 335 supports the substrate W, the first fixed guide surface 335b may guide the lateral surface of the substrate W to restrict the lateral movement of the substrate W.

A support protrusion 356a for supporting the lower surface of the substrate W when the substrate W is placed on the second fixed support surface 336 may be formed on the second fixed support surface 336.

The second fixed guide surface 336b may be provided adjacent to the second fixed support surface 336. The second fixed guide surface 336b may be provided to be perpendicular to the second fixed support surface 336. The second fixed guide surface 336b may face the end of the substrate W in a state in which the lower surface of the substrate W is supported by the second fixed support surface 336. When the second fixed support surface 336 supports the substrate W, the second fixed guide surface 336b may guide the lateral surface of the substrate W to restrict the lateral movement of the substrate W.

Referring back to FIGS. 3 and 4, the rotary guide 340 may support the lower surface region of the edge of the substrate W placed on the hand 330, and simultaneously restrict a lateral movement of the substrate W by guiding the lateral surface of the substrate W. The rotary guide 340 may be provided on the connection part 332a of the support plate 332. The rotary guide 340 may be installed on the connection part 332a of the support plate 332 by a fixed block 351 to be described later, and may be provided to be rotatable with respect to the support plate 332 with respect to a rotation shaft C. The rotary guide 340 may be located at a rear end of the upper surface of the support plate 332.

The rotary guide 340 may be rotated with respect to the rotation shaft C to switch positions between a first state supporting the substrate W at the first height h1 and a second state supporting the substrate W at the second height h2.

The rotary guide 340 is provided as a body having a first rotary support surface 341, a first rotary guide surface 342, a second rotary support surface 343, a second rotary guide surface 344, a first hinge 345, and a second hinge 346.

The first rotary support surface 341 may support the substrate W. A support protrusion 341a for supporting the lower surface of the substrate W may be formed on the first rotary support surface 341. The first rotary support surface 341 is provided to horizontally support the substrate W when the rotary guide 340 is in the first state. The first rotary support surface 341 may support the substrate W at a first height h1 when the rotary guide 340 is in the first state.

The first rotary guide surface 342 is provided adjacent to the first rotary support surface 341. The first rotary guide surface 342 is provided perpendicular to the first rotary support surface 341. The first rotary guide surface 342 may face the end of the substrate W in a state in which the lower surface of the substrate W is supported by the first rotary support surface 341. When the first rotary support surface 341 supports the substrate W, the first rotary guide surface 342 may guide the lateral surface of the substrate W to restrict the lateral movement of the substrate W.

The second rotary support surface 343 may support the substrate W. A support protrusion 343a for supporting the lower surface of the substrate W may be formed on the second rotary support surface 343. The second rotary support surface 343 is provided to horizontally support the substrate W when the rotary guide 340 is in the second state. The second rotary support surface 343 may support the substrate W at the second height h2 when the rotary guide 340 is in the second state.

The second rotary guide surface 344 is provided adjacent to the second rotary support surface 343. The second rotary guide surface 344 is provided perpendicular to the second rotary support surface 343. The second rotary guide surface 344 may face the end of the substrate W in a state in which the lower surface of the substrate W is supported by the second rotary support surface 343. When the second rotary support surface 343 supports the substrate W, the first rotary guide surface 344 may guide the lateral surface of the substrate W to restrict the lateral movement of the substrate W.

The first rotary support surface 341 and the second rotary support surface 343 are formed to be inclined with respect to each other on the body of the rotary guide 340, and as the rotary guide 340 rotates, any one of the first rotary support surface 341 and the second rotary support surface 343 may be provided to support the substrate W.

The rotary guide 340 is connected to the fixed block 351 to be described later through the first hinge 345, and is connected to a link 355 to be described later through the second hinge 346. The second hinge 346 may be disposed to be more spaced apart from the fixed guide 334 than the first hinge 345.

The guide driving unit 350 rotates the rotary guide 340 to switch positions between the first state that supports the substrate W at the first height h1 and the second state that supports the substrate W at the second height h2. The guide driving unit 350 includes a fixed block 351, a moving block 353, a link 355, an LM guide 357, and a driver 359.

The fixed block 351 fixes the rotation shaft C of the rotary guide 340. The fixed block 351 may be fixedly installed on the hand support 320. The fixed block 351 and the rotary guide 340 may be connected to each other through the first hinge 345. The first hinge 345 may function as the rotation shaft C for rotating the rotary guide 340.

The LM guide 357 is disposed on the hand support 320. The LM guide 357 is provided to allow the moving block 353 to move horizontally along the LM guide 357.

The moving block 353 is provided to be horizontally moved on the hand support 320 along the LM guide 357 installed on the hand support 320. The moving block 353 is installed with a third hinge 353a. The moving block 353 is connected to the link 355 through the third hinge 353a. The moving block 353 is horizontally moved by the driver 359 to rotate the rotary guide 340 with respect to the rotation shaft C.

The link 355 connects the rotary guide 340 to the moving block 353. One end of the link 355 is connected to the second hinge 346, and the other end of the link 355 is connected to the third hinge 353a.

The driver 359 moves the moving block 353 along the LM guide 357. For example, the driver 359 may be a linear actuator. The driver 359 may include a motor (not shown) that moves the moving block 353 along the LM guide 357. The driver 359 may be another driving means such as a cylinder.

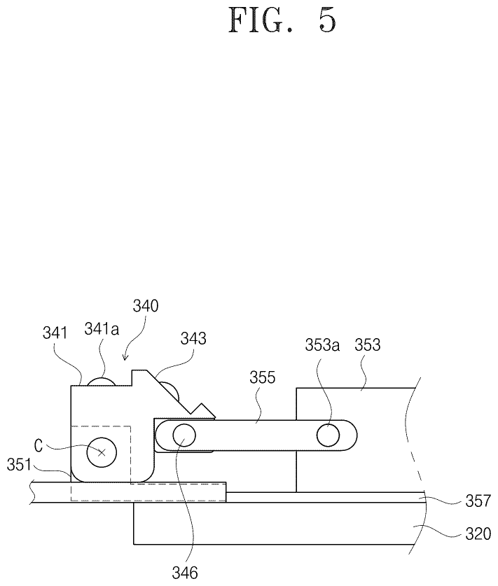

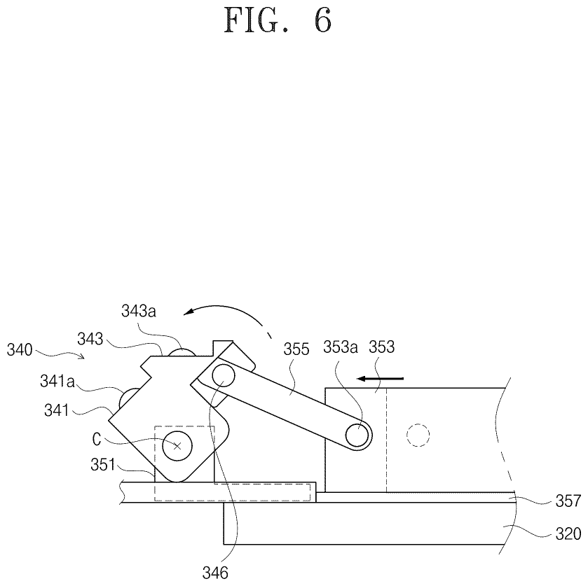

FIG. 5 is a diagram illustrating a state where a rotary guide of FIG. 4 is in a first state, and FIG. 6 is a diagram illustrating a state where the rotary guide of FIG. 4 is in a second state.

Referring to FIGS. 5 and 6, when the moving block 353 moves horizontally along the LM guide 357 by the driver 359, the rotary guide 340 rotates about the rotation shaft C by the link 355 connected to the moving block 353. When the rotary guide 340 rotates and is in the first state, the substrate W may be placed on the first rotary support surface 341. When the rotary guide 340 is in the first state, the rotation shaft C may be disposed below the first rotary support surface 341.

When the rotary guide 340 rotates and is in the second state, the substrate W may be placed on the second rotary support surface 343. When the rotary guide 340 is in the second state, the rotation shaft C may be disposed below the second rotary support surface 343.

Hereinafter, a state in which the hand 330 of the present embodiment supports the substrate will be described in detail with reference to FIGS. 3, 4, 7, and 8.

As illustrated in FIG. 7, when the rotary guide 340 is in the first state, a first substrate W1 is seated on the first fixed support surface 335 and the first rotary support surface 341. That is, when the rotary guide 340 is in the first state, the first fixed support surface 335 and the first rotary support surface 341 together support the first substrate W1. The lateral movement of the first substrate W1 may be restricted by the first fixed guide surface 335b and the first rotary guide surface 342. The first substrate W1 may be positioned at the first height h1 with respect to the support plate 332.

As illustrated in FIG. 8, when the rotary guide 340 is in the second state, a second substrate W1 is seated on the second fixed support surface 336 and the second rotary support surface 343. That is, when the rotary guide 340 is in the second state, the second fixed support surface 336 and the second rotary support surface 343 together support the second substrate W1. The lateral movement of a second substrate W2 may be restricted by the second fixed guide surface 336b and the second rotary guide surface 344. The second substrate W2 may be positioned at the second height h2 with respect to the support plate 332.

When viewed from above, the center position of the first substrate W1 when the fixed guide 334 and the rotary guide 340 support the first substrate W1 at the first height h1 and the center position of the second substrate W2 when the fixed guide 334 and the rotary guide 340 support the second substrate W2 at the second height h2 may be provided differently.

According to the embodiment, the first substrate W1 supported by the hand 330 in the first state and the second substrate W2 supported by the hand 330 in the second state may be substrates in different states. For example, one of the first substrate W1 and the second substrate W2 may be a substrate before processing, and the other may be a substrate after processing. Hereinafter, for convenience of description, it will be described that the first substrate W1 is a substrate before processing, and the second substrate W2 is a substrate after processing.

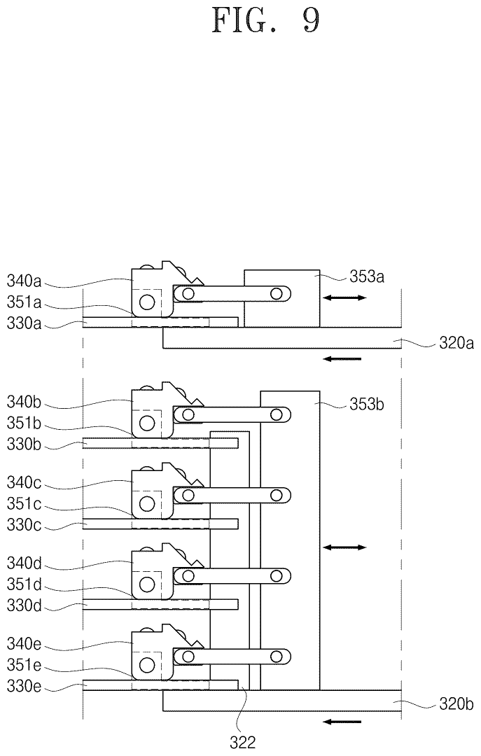

FIG. 9 is a diagram schematically illustrating driving of the hand of the first transfer robot of FIG. 2. As shown in FIGS. 2 and 9, one hand assembly 316 may include a plurality of hands 330. In other words, a plurality of hands 330 may be coupled to one hand support 320. A plurality of hands 330 coupled to one hand support 320 may be stacked to be spaced apart from each other in the vertical direction.

For example, as in FIG. 2 and the aforementioned embodiment, the first transfer robot 300 may be formed of a hand assembly 316a including a hand support 320a to which one hand 330a is coupled, and a hand assembly 316b including a hand support 320b to which four hands 330b, 330c, 330d, and 330e are coupled. Each of the hand assemblies 316a and 316b may be connected to different arms 314a and 314b to be driven simultaneously or independently.

The four hands 330b, 330c, 330d, and 330e may be connected to one hand support 320b through a coupling block 322. The hands 330b, 330c, 330d, and 330e include rotary guides 340b, 340c, 340d, and 340e, respectively. The rotary guides 340b, 340c, 340d, and 340e may be disposed on the support plate 332 of the hands 330b, 330c, 330d, and 330e by the fixed blocks 351b, 351c, 351d, and 351e. The fixed blocks 351b, 351c, 351d, and 351e may be fixedly coupled to the support plate 332 or the coupling block 322. In the same manner as described in FIGS. 3 to 8, as the rotary guides 340b, 340c, 340d, and 340e are rotated and switched between the first state and the second state by the movement of the moving block 353b, each of the hands 330b, 330c, 330d, and 330e may support and transfer the substrate W using different support surfaces at different heights h1 and h2.

Hereinafter, an exemplary embodiment of a method of processing a substrate using the substrate processing apparatus of FIG. 1 will be described. The substrate processing method described below may be performed by the substrate processing apparatus 1 including the index module 10, the buffer chamber 220, the process chamber 260, the first transfer robot 300, and the second transfer robot 244. In addition, the controller 30 may control the configurations of the substrate processing apparatus 1 to perform the substrate processing method described below.

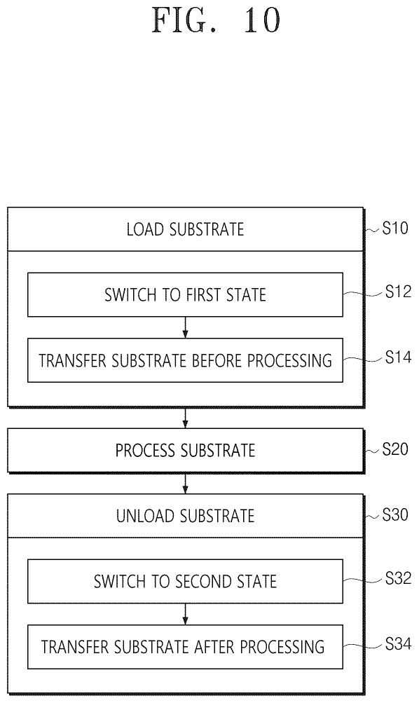

FIG. 10 is a flowchart illustrating a method of processing a substrate using the above-described substrate processing apparatus.

Referring to FIG. 10, the substrate processing method of the present invention includes a substrate loading operation S10, a substrate processing operation S20, and a substrate unloading operation S30.

Referring further to FIG. 7, in the substrate loading operation S10, the first transfer robot 300 provided as the index robot transfers the substrate W1 before processing from the container F in which the substrate W is accommodated to the treating module 20 that processes the substrate W.

In this case, the rotary guide 340 of the hand 330 provided to the first transfer robot 300 is switched to the first state (S12). The substrate W1 before processing is transferred to the treating module 20 in a state of being seated on the first fixed support surface 335 and the first rotary support surface 341 (S14). The substrate W1 before processing may be transferred to the buffer chamber 220 by the first transfer robot 300.

Thereafter, the substrate W1 before processing is transferred from the buffer chamber 220 to the process chamber 260 by the second transfer robot 244, and the substrate processing operation S20 is performed. In the substrate processing operation S20, the substrate W1 before processing is processed in the process chamber 260. When the process chamber 260 is a liquid treating chamber performing a cleaning process for removing process by-products and the like attached to the substrate W, the substrate W1 before processing transferred to the process chamber 260 may be cleaned by the liquid treating chamber.

The substrate processing operation S20 is terminated, and the substrate unloading operation S30 is performed. Referring further to FIG. 8, the substrate W2 after processing is transferred from the process chamber 260 to the buffer chamber 220 by the second transfer robot 244, and is transferred from the buffer chamber 220 to the index module 10 by the first transfer robot 300.

In this case, the rotary guide 340 of the hand 330 provided to the first transfer robot 300 is switched to the second state (S32). The substrate W2 after processing is transferred to the index module 10 in a state of being seated on the second fixed support surface 336 and the second rotary support surface 343 (S34). The substrate W2 after processing may be transferred to the load port 120 by the first transfer robot 300.

The substrate processing method according to the above-described embodiment was described based on the case where the process chamber 260 in which the substrate before processing is loaded into the chamber (S10), the substrate is processed in the chamber (S20), and the substrate after processing is unloaded from the chamber (S30) are performed is the liquid treating chamber for liquid treating the substrate W, as an example.

However, unlike this, the process chamber 260 may be a drying chamber for drying the substrate W, or may further include a drying chamber in addition to the liquid treating chamber. The drying chamber may be a supercritical chamber for drying a substrate using a supercritical fluid.

According to the above-described embodiment, the first transfer robot 300 may be provided as an index robot to transfer the substrate W between the index module 10 and the treating module 20. In this case, a plurality of hands 330 provided to the first transfer robot 300 may transfer the substrate W1 before processing and the substrate W2 after processing by using different support surfaces at different heights h1 and h2.

The hand 330 of the present invention includes the rotary guide 340 that rotates with respect to the rotation shaft C on the support plate 332, and the rotary guide 340 may be position switched between the first state and the second state so as to support the substrate W1 before processing and the substrate W2 after processing using different support surfaces at different heights h1 and h2.

Therefore, since the hand 330 of the present invention is provided to support the substrate W1 before processing and the substrate W2 after processing with different support surfaces, it is possible to prevent reverse contamination of the hand 330 and other substrates W through the substrate W. In other words, it is possible to prevent contaminants, such as particles or fumes, of the contaminated (dirty) substrate W1 before processing from contaminating the cleaned substrate W2 after processing during the process of transferring the substrate W through the hand 330 of the present invention.

In addition, since the substrate W1 before processing and the substrate W2 after processing may be supported and transferred with different support surfaces with one hand 330, both the substrate W1 before processing and the substrate W2 after processing may be transferred with the hand 330, thereby increasing the transfer efficiency of the substrate W.

In addition, compared to the case of transferring the substrate W1 before processing and the substrate W2 after processing through different hands, respectively, the configuration of the first transfer robot 300 may be simplified, the overall height of the hand assembly 316 may be lowered, and the weight of the first transfer robot 300 may be reduced.

In the above embodiment, it is illustrated and described that the rotary guide 340 is installed on the connection part 332a of the support plate 332 by the fixed block 351, and the fixed block 351 is fixedly installed on the hand support 320. However, unlike this, it is sufficient that the fixed block 351 is fixedly installed on the hand assembly 316. For example, the fixed block 351 may be fixedly installed on the support plate 332.

In the above-described embodiment, it has been illustrated and described that the rotary guide 340 rotates by receiving power from the driver 359 through a link. However, unlike this, the rotary guide 340 may be changed to rotate using a known means.

In the above embodiment, it is illustrated and described that the fixed guide 334 includes the first fixed support part supporting the substrate W at the first height h1 and the second fixed support part supporting the substrate W at the second height h2, and the fixed guide 334 has the integrated body including the first fixed support surface 335 and the second fixed support surface 336. However, unlike this, the first fixed support part supporting the substrate W at the first height h1 and the second fixed support part supporting the substrate W at the second height h2 may have separate bodies and may be provided at the front ends of the first finger 332b and the second finger 332c of the support plate 332.

In the above embodiment, only the first transfer robot 300 is described, and a description of the second transfer robot 244 is omitted. However, the configuration of the above-described first transfer robot 300 may be equally applied to the second transfer robot 244.

For example, the second transfer robot 244 may transfer the substrate W1 before processing from the buffer chamber 220 to the process chamber 260 and transfer the substrate W2 from the process chamber 260 to the buffer chamber 220, and transfer the substrate W1 before processing and the substrate W2 after processing in a state of being supported using different support surfaces at different heights h1 and h2.

The second transfer robot 244 may include a plurality of hand assemblies 316 including the hand support 320 coupled to one hand 330. It is a matter of course that the hand assemblies 316 may be connected to the different arms 314, respectively, to drive simultaneously or independently.

In the above embodiment, it has been illustrated and described that the first transfer robot 300 or the second transfer robot 244 is a so-called orthogonal transfer robot in which the hand assembly 316 moves forward or backward with respect to the base 310. However, unlike this, the configuration of the hand assembly 316 described above may be equally applied even when the first transfer robot 300 or the second transfer robot 244 is a so-called SCARA robot.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

What is claimed is:

1. A transfer robot for transferring a substrate, the transfer robot comprising:
a hand assembly including a hand supporting a substrate and a hand support connected to the hand; and
a driving unit for driving the hand assembly,
wherein the hand includes:
a support plate coupled to the hand support to support the substrate;
a fixed guide which is fixedly installed on a front end of an upper surface of the support plate to support a region of a lower surface of an edge of the substrate placed on the support plate;
a rotary guide located at a rear end of the upper surface of the support plate so as to be spaced apart from the fixed guide to support the region of the lower surface of the edge of the substrate; and
a guide driving unit for driving the rotary guide,
the fixed guide includes:
a first fixed support part for supporting the substrate at a first height; and
a second fixed support part for supporting the substrate at a second height different from the first height,
the rotary guide is rotatably provided with respect to the support plate based on a rotation shaft and includes a body having a first rotary support surface capable of supporting the substrate at the first height together with the first fixed support part and a second rotary support surface capable of supporting the substrate at the second height together with the second fixed support part, and
the guide driving unit is provided to rotate the body to switch between a first state in which the first rotary support surface supports the substrate together with the first fixed support part and a second state in which the second rotary support surface supports the substrate together with the second fixed support part.

2. The transfer robot of claim 1, wherein the first rotary support surface and the second rotary support surface are provided obliquely to each other.

3. The transfer robot of claim 1, wherein the rotary guide further includes:
a first rotary guide surface for guiding a lateral surface of the substrate when the first rotary support surface supports the substrate; and
a second rotary guide surface for guiding the lateral surface of the substrate when the second rotary support surface supports the substrate.

4. The transfer robot of claim 1, wherein support protrusions for supporting a bottom surface of the substrate are formed on the first rotary support surface and the second rotary support surface, respectively.

5. The transfer robot of claim 1, wherein the guide driving unit includes:
a moving block provided to move horizontally on the hand support; and
a link connecting the moving block and the rotary guide.

6. The transfer robot of claim 5, wherein the rotary guide further includes:
a first hinge connected to the hand assembly; and
a second hinge to which one end of the link is connected,
the moving block includes a third hinge to which the other end of the link is connected, and
the first hinge is a rotation shaft on which the rotary guide rotates.

7. The transfer robot of claim 6, wherein when the rotary guide is in the first state, the rotation shaft is disposed below the first rotary support surface, and
when the rotary guide is in the second state, the rotation shaft is disposed below the second rotary support surface.

8. The transfer robot of claim 1, wherein the fixed guide includes:
a first fixed support surface provided as the first fixed support part; and
a second fixed support surface provided as the second fixed support part.

9. The transfer robot of claim 1, wherein the support plate includes:
a connection part coupled to the hand support; and
a first finger and a second finger extending from the connection part, and
the fixed guide is provided to each of front ends of the first finger and the second finger.

10. The transfer robot of claim 1, wherein a plurality of hand assemblies are provided, and the plurality of hand assemblies is provided to be spaced apart from each other in a vertical direction.

11. The transfer robot of claim 10, wherein the hand assembly is provided so that one or more hands are coupled to one hand support to be spaced apart in the vertical direction.

12. The transfer robot of claim 1, wherein the transfer robot further includes:
a base; and
an arm of which one end is connected to the base and the other end is connected to the hand assembly, and
the arm is provided to be movable forward and backward with respect to the base.

13. The transfer robot of claim 1, wherein when viewed from the top,
a center position of the substrate when the fixed guide and the rotary guide support the substrate at the first height and a center position of the substrate when the fixed guide and the rotary guide support the substrate at the second height are provided differently.

14. An apparatus for processing a substrate, the apparatus comprising:
an index module including a load port for loading and unloading a substrate;
a treating module including a process chamber for processing a substrate; and
a controller; and
the transfer robot of claim 1 for transferring the substrate between the index module and the treating module,
wherein the controller switches a state of the rotary guide to transfer the substrate in a state where the hand supports a first substrate and a second substrate at different heights when the hand transfers the first substrate and the second substrate.

15. The apparatus of claim 14, wherein the fixed guide includes:
a first fixed support surface provided as the first fixed support part; and
a second fixed support surface provided as the second fixed support part.

16. The apparatus of claim 14, wherein the first substrate is a substrate before processing that has not been processed in the process chamber, and
the second substrate is a substrate after processing that has been processed in the process chamber, and
the controller controls the fixed guide and the rotary guide to support the substrate before processing at the first height by switching the rotary guide to the first state when the hand transfers the substrate before processing, and
the controller controls the fixed guide and the rotary guide to support the substrate after processing at the second height by switching the rotary guide to the second state when the hand transfers the substrate after processing.

17. The apparatus of claim 16, wherein when viewed from the top, a center position of the substrate when the fixed guide and the rotary guide support the substrate at the first height and a center position of the substrate when the fixed guide and the rotary guide support the substrate at the second height are provided differently.

18. A transfer robot for transferring a substrate, the transfer robot comprising:
a base;
an arm which is connected to the base and is movable forward and backward with respect to the base;
a hand assembly including a hand coupled to the arm and supporting the substrate and a hand support connected to the hand; and
a driving unit for driving the hand assembly,
wherein the hand includes:
a support plate coupled to the hand support to support the substrate;
a fixed guide which is fixedly installed on a front end of an upper surface of the support plate to support a region of a lower surface of an edge of the substrate placed on the support plate;
a rotary guide located at a rear end of the upper surface of the support plate so as to be spaced apart from the fixed guide to support the region of the lower surface of the edge of the substrate; and
a guide driving unit for driving the rotary guide,
the support plate includes:
a connection part coupled to the arm; and
a first finger and a second finger extending from the connection part, and
the fixed guide is provided to each of front ends of the first finger and the second finger,
the fixed guide includes:
a first fixed support surface for supporting the substrate at a first height; and
a second fixed support surface for supporting the substrate at a second height different from the first height,
the rotary guide is rotatably provided with respect to the support plate based on a rotation shaft and includes a body having a first rotary support surface capable of supporting the substrate at the first height together with the first fixed support surface and a second rotary surface capable of supporting the substrate at the second height together with the second fixed support surface,
the guide driving unit is provided to rotate the rotary guide so that the rotary guide switches between a first state supporting the substrate at the first height and a second state supporting the substrate at the second height,
the first state is a state in which the first fixed support surface and the first rotary support surface support the substrate at the first height, and
the second state is a state in which the second fixed support surface and the second rotary support surface support the substrate at the second height.

19. The transfer robot of claim 18, wherein a plurality of hand assemblies are provided, and the plurality of hand assemblies are provided to be spaced apart from each other in a vertical direction, and
each of the hand assemblies is provided so that one or more hands are coupled to one hand support to be spaced apart in the vertical direction.

20. The transfer robot of claim 18, further comprising:
a controller,
the controller controls the fixed guide and the rotary guide to support the substrate before processing at the first height by switching the rotary guide to the first state when the hand supports the substrate before processing, and
the controller controls the fixed guide and the rotary guide to support the substrate after processing at the second height by switching the rotary guide to the second state when the hand supports the substrate after processing.
